(19) United States
(12) Patent Application Publication
(10) Pub. No.: US 2007/0054045 A1
(43) Pub. Date: Mar. 8, 2007

(54) METHOD FOR CONDITIONING CHEMICAL VAPOR DEPOSITION CHAMBER

(76) Inventor: Hsienting Hou, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,998

(22) Filed: Aug. 25, 2005

(51) Int. Cl. C23C 16/00

(52) U.S. Cl. 427/248.1; 118/724

(57) ABSTRACT

A method for conditioning a heater of a CVD chamber by forming a pre-coating layer on the surface of the heater is provided. Hence, the surface condition of the heater is improved for better thermal efficiency and the surface of the heater is protected from the possible damages of the cleaning gases. Therefore, the lifetime of the heater becomes longer and costs and recovery time for the preventive maintenance of the CVD system can be reduced.

### BACKGROUND OF THE INVENTION

1. Field of the Invention

The present invention relates to a method for conditioning the chamber of a chemical vapor deposition system. More particularly, the present invention relates to a method for conditioning the chamber of a chemical vapor deposition system by pre-coating the chamber.

2. Description of the Related Art

Chemical vapor deposition (CVD) includes atmospheric pressure CVD (APCVD), low pressure CVD (LPCVD), plasma enhanced CVD (PECVD), etc. Generally, every CVD system comprises a reactor, a gas transporting system, a venting system, a process controlling system, etc.

Currently, semiconductor system manufacturers use mainly batch type processing systems for CVD process steps. However, the conventional batch processing systems take considerable cycle time, and have the issue of large thermal budget. Consequently, single wafer type CVD systems, which have a reduced cycle time, have been expected to replace vertical batch systems in certain process steps. Furthermore, single wafer type processing CVD systems having better process capabilities are particularly useful, as semiconductor devices become more miniaturized and require various new films.

After the CVD process of semiconductor manufacture, it is necessary to clean up the materials of the deposited material and others contaminants inside the CVD chamber. Commonly, perfluorocarbons (PFCs), nitrogen trifluoride (NF₃), and other gases are currently used as cleaning gases. These gases are introduced to the CVD chamber with plasma condition and radicals are generated inside of the chamber. These radicals are reacted with the deposited materials and contaminants to produce gaseous compounds, and then these compounds are pumped out of the CVD chamber.

However, the cleaning gas such as NF3 may cause damages to the heater in the reactor and reduce the lifetime of the heater. Therefore, the costs and the required time of maintaining the CVD systems are increased.

### SUMMARY OF THE INVENTION

It is therefore an objective of the invention to provide a method for conditioning a heater of a CVD chamber by forming a pre-coating layer on the surface of the heater. Hence, the surface condition of the heater is improved for better thermal efficiency and the surface of the heater is protected from the possible damages of the cleaning gases. Therefore, the lifetime of the heater becomes longer and costs and recovery time for the preventive maintenance of the CVD system can be reduced.

To achieve these and other advantages and in accordance with the purpose of the present invention, as embodied and broadly described herein, the present invention provides a method for conditioning a heater in the chamber of a chemical vapor deposition system. The method is suitable for conditioning the heater surface of the chamber before performing the main chemical vapor deposition process and before performing the cleaning process and comprises the steps of: introducing a conditioning gas into the chamber of the CVD system, and the conditioning gas includes a carrier gas and a silicon-containing gas; subjecting the heater in the chamber to the conditioning gas; forming a pre-coating layer on a surface of the heater in the chamber, and the pre-coating layer includes at least a silicon layer; and forming a material layer on the pre-coating layer. The material of the material layer is different to that of the pre-coating layer.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic, cross-sectional view of a LPCVD system.

FIG. 2 is a flowchart of the method for conditioning the CVD chamber according to a preferred embodiment of this invention.

### DESCRIPTION OF THE PREFERRED EMBODIMENTS

Reference will now be made in detail to a preferred embodiment of the invention, examples of which are illustrated in the accompanying drawings. Wherever possible, the same reference numbers are used in the drawings and the description to refer to the same or like parts. LPCVD system is used as an example herein; however, the present invention is not limited to be applicable to only LPCVD system but applicable to any suitable CVD systems.

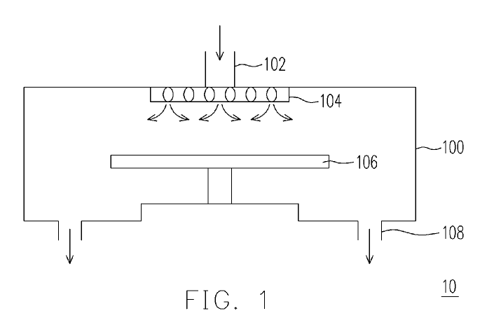

FIG. 1 is a schematic, cross-sectional view of a LPCVD system.

First, as shown in FIG. 1, a CVD system 10 comprises a chamber 100, a gas source inlet 102, a shower head 104, a heater (also a susceptor for the wafer) 106 and vents 108. Of course, the CVD system 10 further includes at least a gas transporting system, a venting system, a wafer transporting system and/or a process control system etc.; however, for simplifying the illustration, these elements are not shown in this schematic cross-sectional view of the CVD system.

During the cleaning process for the CVD chamber 100, mixing gases are pumped into the chamber 100 through the gas inlet 102. The mixing gases include a medium gas and a cleaning gas. The medium gas can be argon, or nitrogen gas and the cleaning gas can be nitrogen trifluoride (NF₃), for example.

However, the heater 106 is directly exposed to the cleaning gas and suffers from the damages caused by the etching of the cleaning gas. In order to solve such problem, the present invention proposed a method for conditioning the CVD chamber by forming a pre-coating layer on the heater.

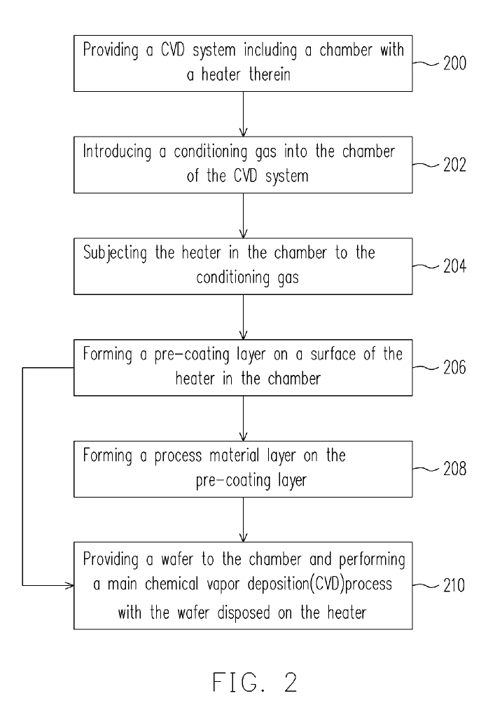

FIG. 2 is a flowchart of the method for conditioning the CVD chamber according to a preferred embodiment of this invention.

In step 200, a CVD system including a chamber with a heater therein is provided. In step 202, a conditioning gas is pumped into the chamber. The conditioning gas includes a carrier gas and a silicon-containing gas. The carrier gas can be argon, nitrogen, hydrogen, or helium gas, while the silicon containing gas can be silane (SiH₄) or di-silane (Si₂H₆), for example. In step 204, the heater in the chamber is subjected to the conditioning gas for deposition reactions. Next, in step 206, a pre-coating layer is deposited on the surface of the heater in the CVD chamber. The pre-coating layer includes at least a silicon layer. The flow rate ratio of the carrier gas to the conditioning gas and the pressure of the chamber are adjusted to a predetermined level. The flow rate of the conditioning gas or the carrier gas may vary in a wide range according to the practical condition. In the example, the preferred flow rate of the conditioning gas is about 200 standard cubic centimeter per minute (sccm), while the preferred flow rate of the carrier gas is about 50 sccm, for example. The resultant pre-coating layer has a thickness ranging from about 2000 Angstroms to about 2 microns, preferably ranging between about 5000-6000 Angstroms.

It is noted that steps 200-206 are performed before subjecting the wafer to the main chemical vapor deposition process, so that the pre-coating layer formed on the heater can condition the surface of the heater for better thermal efficiency. By forming a pre-coating layer on the heater, a smoother surface is obtained for the heater and the heat transmission from the heater to the wafer is improved.

Optionally, a process material layer is formed on the pre-coating layer by performing the main chemical vapor deposition process without providing a wafer to the chamber, in step 208. Depending on the reaction gases used in the main chemical vapor deposition process being performed, the process material layer can be a silicon oxide layer or a silicon nitride layer, for example. If the main chemical vapor deposition process is a nitride deposition process, the process material layer is a nitride layer, for example. If the main chemical vapor deposition process is an oxide deposition process, the process material layer is an oxide layer, for example. However, according to the method of the present invention, a layer of any suitable material can be formed on the pre-coating layer, rather than only the process material layer; as long as, the material of the layer formed on the pre-coating layer is different to the material of the pre-coating layer. In general, the pre-coating layer provides the major protective effect and the later formed material layer has satisfactory adhesion toward the pre-coating layer.

In step 210, a wafer is provided to the chamber and the main chemical vapor deposition process is performed with the wafer disposed on the heater.

It is known to one skilled in the art that, during numerous cycles of deposition processes, the chamber will get contaminated with deposited film residues and other byproducts of the processes, and in-situ cleaning of the chamber and its internal components is required.

Because the heater in the CVD chamber has been conditioned, during the cleaning process, the heater in the chamber is protected from the damages of the cleaning gases by the pre-coating layer and the process material layer. Therefore, the lifetime of the heater is extended and the costs and maintenance time for the CVD system are decreased. As described above, by performing a conditioning process using the conditioning gas and optionally performing the main CVD process without providing the wafer, the heater is in-situ coated and the surface condition of the heater is modified.

It is clear from the above discussion that the present method is not limited to any particular structure of CVD chambers such as those shown in the figures.

The present invention has the following advantages:

1. By forming the pre-coating layer on the heater and/or the process material layer on the pre-coating layer, the surface condition of the heater is improved, thus enhancing the thermal efficiency and increasing uniformity of the later deposited films on the wafer.

2. In the invention, the pre-coating layer protects the surface of the heater, so that the chamber can be cleaned by the cleaning gases without damaging the surface of the heater. Therefore, the lifetime of the heater becomes longer and costs and recovery time for the preventive maintenance of the CVD system can be reduced.

3. The method proposed by the present invention is compatible with the currently existing manufacturing processes or the commonly used CVD systems; thus the method of the present invention is suitable for manufacturers to utilize.

It will be apparent to those skilled in the art that various modifications and variations can be made to the method of the present invention without departing from the scope or spirit of the invention. In view of the foregoing, it is intended that the present invention cover modifications and variations of this invention provided they fall within the scope of the following claims and their equivalents.

What is claimed is:

1. A method for conditioning a heater in a chamber of a chemical vapor deposition (CVD) system, the method comprising the steps of:
introducing a conditioning gas into the chamber of the CVD system, wherein the conditioning gas includes a carrier gas and a silicon-containing gas;
subjecting the heater in the chamber to the conditioning gas;
forming a pre-coating layer on a surface of the heater in the chamber, wherein the pre-coating layer includes at least a silicon layer; and
providing a wafer to the chamber and performing a main chemical vapor deposition (CVD) process with the wafer disposed on the heater.

2. The method of claim 1, wherein the method further comprises forming a process material layer on the pre-coating layer by performing the main chemical vapor deposition (CVD) process without the wafer, after the step of forming the pre-coating layer and before the step of providing the wafer to the chamber.

3. The method of claim 2, wherein the process material layer includes a silicon oxide layer.

4. The method of claim 2, wherein the process material layer includes a silicon nitride layer.

5. The method of claim 1, wherein the silicon-containing gas includes silane (SiH₄).

6. The method of claim 1, wherein the silicon-containing gas includes di-silane (Si₂H₆).

7. The method of claim 1, wherein the carrier gas is argon, nitrogen, hydrogen, or helium.

8. The method of claim 1, wherein the pre-coating layer has a thickness ranging from about 2000 Angstroms to about 2 microns.

9. The method of claim 1, wherein the pre-coating layer has a thickness ranging between about 5000-6000 Angstroms.

10. A method for conditioning a heater in a chamber of a chemical vapor deposition (CVD) system, the method comprising the steps of:
introducing a conditioning gas into the chamber of the CVD system;
subjecting the heater in the chamber to the conditioning gas;
forming a coating layer on a surface of the heater in the chamber; and
forming a material layer on the coating layer, wherein a material of the material layer is different to that of the coating layer.

11. The method of claim 10, wherein the conditioning gas includes a silicon-containing gas.

12. The method of claim 11, wherein the silicon-containing gas includes silane (SiH₄).

13. The method of claim 11, wherein the silicon-containing gas includes di-silane (Si₂H₆).

14. The method of claim 10, wherein the coating layer has a thickness ranging from about 2000 Angstroms to about 2 microns.

15. The method of claim 10, wherein the pre-coating layer has a thickness ranging between about 5000-6000 Angstroms.
